(19) United States
(12) Patent Application Publication
(10) Pub. No.: US 2011/0020623 A1
(43) Pub. Date: Jan. 27, 2011

(54) Method and Apparatus for Repairing an Optical Component Substrate Through Coating

(75) Inventors: Daniel B. Mitchell, Port McNicoll (CA); Geoffrey G. Harris, Midland (CA); Douglas J. Brown, Midland (CA)

Correspondence Address: HAYNES AND BOONE, LLP;IP Section, 2323 Victory Avenue, Suite 700, Dallas, TX, 75219, US

(73) Assignee: RAYTHEON COMPANY, Waltham, MA (US)

(21) Appl. No.: 12/507,435

(22) Filed: Jul. 22, 2009

(51) Int. Cl. B32B 7/02; B05D 5/06; C23C 14/34

(52) U.S. Cl. 428/217; 427/162; 204/192.26; 428/212

(57) ABSTRACT

A method involves depositing on a surface of an optical substrate an optical layer made of a substance that has an index of refraction approximately equal to an index of refraction of the optical substrate, the optical substrate and the layer collectively defining a multi-section substrate in which the optical substrate and the optical layer serve as respective sections. According to a different aspect, an apparatus includes a multi-section substrate having a first section that is an optical substrate with a surface, and having a second section that is an optical layer provided on the surface and made of a substance having an index of refraction approximately equal to an index of refraction of the optical substrate.

### FIELD OF THE INVENTION

This invention relates in general to optical components and, more particularly, to techniques for fabrication and/or repair of the substrate of an optical component.

### BACKGROUND

Optical components such as lenses, domes and windows are typically made from a larger blank, which is ground and/or polished down to the shape needed. Even after shaping, the part may sometimes be out of specification. As one example, the part may have a high-tolerance specification because it is intended for use in a high-precision device, such as a high-end microscope or an expensive camera. As another example, the part may be made from a material that is difficult to accurately grind and/or polish.

When the part reaches a point during fabrication when it should in theory be completed, but is actually found to be out of specification, the part is reworked in order to try to bring it into compliance with the specification. The reworking removes more material. For particularly difficult parts, several rounds of reworking may be carried out. Each time the part is reworked, more material is removed, and the part becomes thinner. At some point, the part may become too thin to be used.

A similar situation exists in the case of a part that was previously fabricated and then used for a period of time, such that an outside surface became scratched or otherwise physically damaged. A repair of the part can be attempted, involving removing coatings (if any),and then grinding and/or polishing the damaged surface. However, this thins the part. At some point, possibly after multiple attempts at repair, the part may become too thin.

Where grinding and/or polishing of an optical part causes it to become too thin, the traditional approach has been to scrap the thin part, purchase a new blank, and begin the manufacturing process again from the very beginning. While this approach has been generally adequate for its intended purposes, it has not been satisfactory in all respects, especially in regard to optical components that are relatively expensive. The existing approach typically involves undesirable cost and delay, reflected not only in the cost of the new blank, but also in the cost of labor, material and equipment used in creating a part that ultimately ends up being discarded.

### BRIEF DESCRIPTION OF THE DRAWINGS

A better understanding of the present invention will be realized from the detailed description that follows, taken in conjunction with the accompanying drawings, in which:

FIG. 1 is diagrammatic sectional side view of an apparatus that is a conventional optical component, in particular a substrate that is a lens, shown at a selected stage during fabrication thereof.

FIG. 2 is a diagrammatic sectional side view similar to FIG. 1, but showing that several successive reworking operations have removed material from one side of the lens, resulting in a new side surface.

FIG. 3 is a diagrammatic sectional side view of the thin lens of FIG. 2, with the addition of a coating on a side surface thereof.

FIG. 4 is diagrammatic sectional side view of a conventional coating apparatus that has therein the coated lens of FIG. 3, and another similar coated lens.

### DETAILED DESCRIPTION

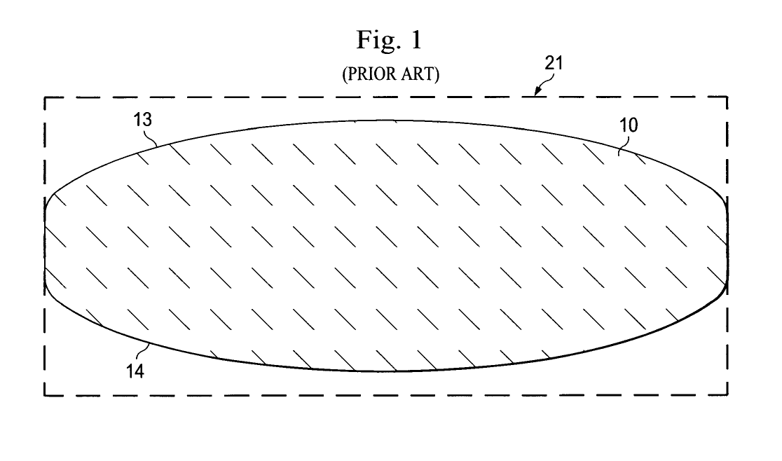

FIG. 1 is diagrammatic sectional side view of an apparatus that is a conventional optical component, in particular a substrate that is a lens 10, shown at an selected stage during fabrication thereof. Although the optical component 10 in FIG. 1 is a lens, it could alternatively be some other type of optical component, such as a window or a dome. The lens 10 has curved surfaces 13 and 14 on opposite sides thereof. The process of manufacturing the lens 10 begins with a blank that is shown diagrammatically at 21. Although the blank 21 in FIG. 1 has an initial shape that is generally rectangular, the blank could alternatively have some other initial shape. For example, the blank could have an initial shape that is closer to the shape of the desired lens 10.

Material of the blank 21 is removed by grinding and/or polishing, in order to obtain the lens 10 with the desired shape. FIG. 1 represents a state of the lens 10 in which the fabrication of the lens should in theory be completed. However, when the lens is tested for accuracy at this point, it is sometimes determined that the lens does not meet one or more of its design specifications, for example because it is a high-tolerance part, or because it happens to be made of a material that is hard to accurately shape. Accordingly, when a lens reaches the point at which it should theoretically be completed but fails to meet one or more of its specifications, the lens is reworked, which has the effect of removing additional material. In some cases, there may be multiple cycles of reworking and retesting, involving the repeated removable of material.

A similar situation can arise where a component was previously fabricated and then used for a period of time, and an outside surface has become scratched or otherwise physically damaged. A repair can then be attempted through grinding and/or polishing, which removes material and thins the part. There may be multiple cycles of reworking and retesting, involving the repeated removable of material.

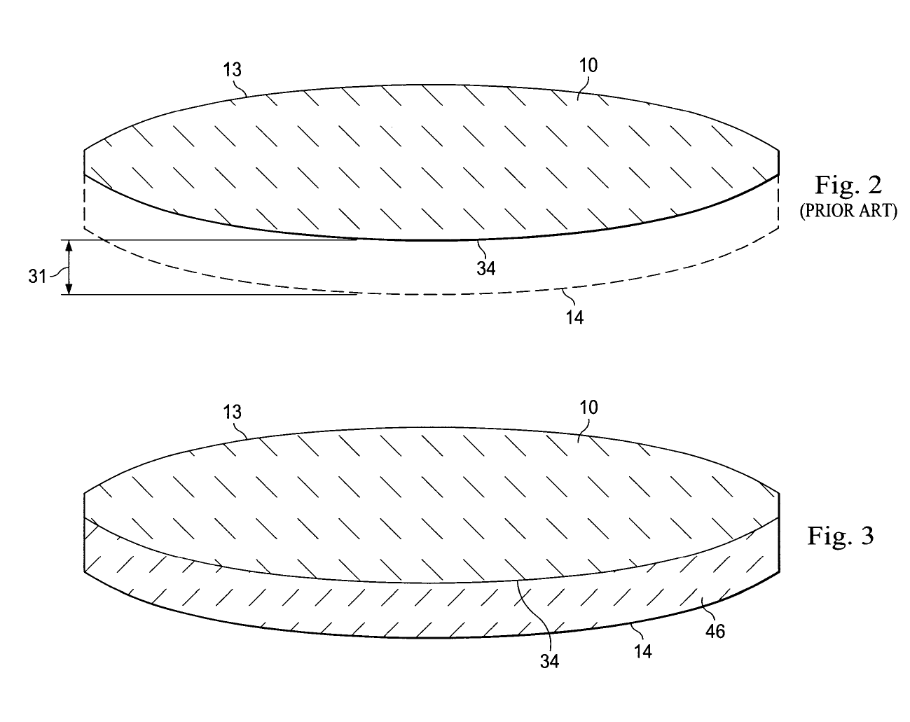

FIG. 2 is a diagrammatic sectional side view similar to FIG. 1, but showing that several successive reworking operations have removed an amount of material 31 from one side of the lens 10, resulting in a new side surface 34. At some point, multiple cycles of reworking may cause the lens 10 to become too thin for actual use in the intended application. When this occurs, the traditional course of action is to scrap the thin lens, select another blank 21 (FIG. 1), and begin the entire fabrication process again from the beginning.

To avoid the traditional approach of scrapping a part that has become too thin, one aspect of the invention involves adding material where material has been removed. In this regard, FIG. 3 is a diagrammatic sectional side view of the thin lens 10 as shown in FIG. 2, with the addition of a coating 46 on the side surface 34 thereof. The material selected for the coating 46 is a material that has substantially the same index of refraction as the material of the lens 10, in order to avoid optical interference effects that would ruin the optical properties of the resulting optical component defined by the lens 10 with the coating 46 thereon. Depending on the material of the lens 10, it may be possible to make the coating 46 from the same material. However, even if the lens and coating are each made from the same material, in the sense that the materials are chemically equivalent, this does not automatically guarantee that the lens and coating will have the same index of refraction. For example, the lens and the coating will typically be formed by different processes, and the lens and coating may therefore have different crystalline structures, such as where the coating has a more amorphous crystalline structure. In some cases, a closer match in indexes of refraction may be obtained by making the coating 46 from a material different from the material of the lens 10.

Beyond matching the indexes of refraction of the lens 10 and coating 46, it can also be advantageous to obtain a match in the hardnesses and/or coefficients of thermal expansion of the lens 10 and coating 46. If the hardnesses are approximately the same, then the lens with the coating thereon can be ground or polished under the same conditions that would be used for the lens alone. In contrast, if the coating has a hardness that is significantly different from the hardness of the lens, the grinding and/or polishing conditions may need to be adjusted to accommodate the higher or lower hardness of the coating 46. Matching the coefficients of thermal expansion has the advantage of reducing shear forces that can occur at the interface between the lens and coating in response to temperature changes.

In a situation where the coating 46 is made from a material that is softer than the material of the lens 10, the coating should be formed on the less-exposed surface of the lens. For example, if the lens will be mounted in a housing so that one surface is exposed to ambient conditions external to the housing, whereas the other surface will face the interior of the housing, the soft coating should be applied to the latter surface.

In some cases, there may be an existing coating material with a refractive index that closely matches the refractive index of the lens substrate. But if a coating material with the requisite index of refraction is not readily available, it may be possible to alter the index of refraction of an existing coating material by modifying process conditions used during the coating process, for example by changing the temperature, changing ion assist parameters, or changing an oxygen flow rate (for oxides). Still another possibility is to mix two or more existing coating materials that have different indexes of refraction, in order to obtain a mixture of those materials that provides the requisite index of infraction.

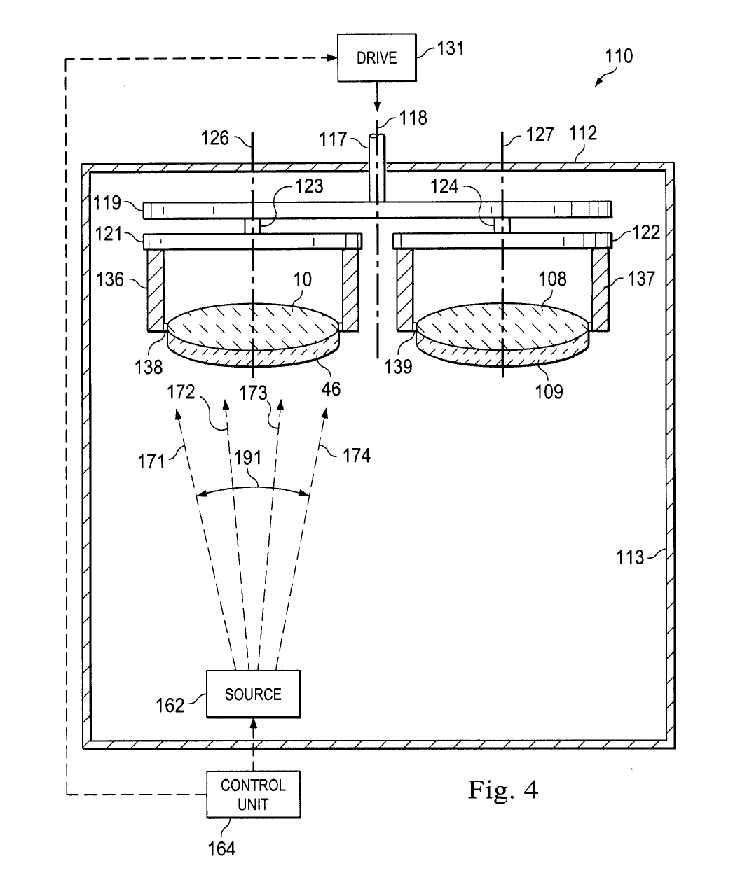

FIG. 4 is diagrammatic sectional side view of a conventional coating apparatus 110 that has therein the lens 10 with coating 46 (FIG. 3), and also another similar lens 108 with a similar coating 109. The coating apparatus 110 includes a housing 112 with a chamber 113 therein. During a typical coating operation, a vacuum is maintained in the chamber 113 by a not-illustrated vacuum pump. The housing 112 supports a primary axle 117 for rotation about a primary vertical axis 118. A support part 119 is supported on the axle 117 within the chamber 113 for rotation with the axle about the axis 118. In the disclosed embodiment, the support 119 is disk-shaped, but it could alternatively have any other suitable shape.

The support part 119 rotatably supports two workpiece support members 121 and 122. More specifically, two additional vertical axles 123 and 124 are rotatably supported on the support part 119. These two additional axles are spaced circumferentially from each other about the primary axle 117, and they each rotate about a respective additional vertical axis 126 or 127. The two support members 121 and 122 are each fixedly supported on a respective one of the axles 123 and 124 for rotation therewith about the associated axis 126 or 127. In the disclosed embodiment, the support members 121 and 122 are disk-shaped, but they could each alternatively have any other suitable shape. Although FIG. 4 shows two workpiece support members 121 and 122 having respective axles 123 and 124, it would alternatively be possible to have one or more additional workpiece support members with respective axles, where the axles for all workpiece support members are spaced circumferentially from each other about the primary axle 117.

A drive mechanism 131 such as an electric motor is coupled to the axle 117, in order to effect rotation of the axle 117 and the support part 119. A not-illustrated planetary gearing mechanism of a well-known type is provided and, in response to rotation of the support part 119 with respect to the housing 112, effects rotation of the additional axles 123 and 124 with respect to the support part 119. Thus, the workpiece support members 121 and 122 each undergo planetary movement about the primary axis 118 with respect to the housing 112. Each of the workpiece support members 121 and 122 has fixed thereon a respective workpiece support fixture 136 or 137. The workpiece support fixtures 136 and 137 are each a cylindrical sleeve with an annular piece of double-sided adhesive tape 138 or 139 on the inner surface thereof at the lower end. The tape 138 engages a peripheral edge of the lens 10 in order to fixedly but removably support that lens on the fixture 136, and the tape 139 engages a peripheral edge of the lens 108 in order to fixedly but removably support that lens on the fixture 137.

Although the disclosed embodiment uses double-sided adhesive tape 138 and 139 to support the lenses 10 and 108, it would alternatively be possible to support the lenses on the workpiece support members 121 and 122 in any other suitable manner. As one example, the fixtures 136 and 137 could each have at the lower end thereof a radially inwardly projecting annular flange that engages the peripheral edge of the surface on the underside of the corresponding lens 10 or 108.

The primary axle 117, the support part 119, the additional axles 123 and 124, the workpiece support members 121 and 122, and the workpiece support fixtures 136 and 137 collectively serve as a workpiece support mechanism. For simplicity and clarity, FIG. 4 shows each of the workpiece support members 121 and 122 with just one workpiece support fixture 136 or 137 thereon. However, it would alternatively be possible for each of the workpiece support members 121 and 122 to have a plurality of workpiece support fixtures thereon.

The apparatus 110 forms the respective coatings 46 and 109 on the lenses 10 and 108. In this regard, the coating apparatus 110 includes a source 162 within the housing 112, in a lower portion of the chamber 113. The source 162 is spaced downwardly from the support part 119. The source 162 and the drive mechanism 131 are both controlled by a control unit 164 of a known type. Although FIG. 4 shows only a single source 162, it would alternatively be possible to provide two or more sources in the apparatus 110. In the disclosed embodiment, the source 162 is spaced radially from the primary axis 118, and is positioned approximately below the path of travel of the workpiece support members 121 and 122. However, it would alternatively be possible for the source 162 to be positioned at any of a variety of other locations within the housing 112.

The source 162 is a device of a type well known in the art, and is therefore described here only briefly. In the disclosed embodiment, the source 162 is a type of device commonly referred to as an electron beam evaporator. However, the source 162 could alternatively be any other suitable type of device. The source 162 contains one or more different materials that can be used to form the coatings 46 and 109. The source 162 can evaporate only one such material in order to form the coatings 46 and 109. Alternatively, the source 162 can carry out co-deposition by simultaneously evaporating a combination of two or more of the materials therein in order to form the coatings 46 and 109.

When the source 162 is evaporating one or more of the materials therein, a plume of the evaporated material(s) travels upwardly, as indicated diagrammatically by arrows 171-174. The plume 171-174 has a dispersion angle 191. The plume 171-174 from the source 162 coats the lower surfaces of the lenses 10 and 108 as the lenses pass above the source 162, thereby forming the coatings 46 and 109.

Although the coating apparatus 110 shown in FIG. 4 is an evaporation system that utilizes an electron beam evaporator 162 to form the coatings 46 and 109, it would alternatively be possible to form the coatings 46 and 109 in any other suitable manner. For example, the uncoated lenses 10 and 108 could be placed in a conventional sputter apparatus, and the coatings 46 and 109 could be formed by carrying out sputtering using one or more sputter targets that emit one material or a combination of materials needed for the coatings 46 and 109.

Although selected embodiments have been illustrated and described in detail, it should be understood that a variety of substitutions and alterations are possible without departing from the spirit and scope of the present invention, as defined by the claims that follow.

What is claimed is:

1. A method comprising depositing on a surface of an optical substrate an optical layer made of a substance that has an index of refraction approximately equal to an index of refraction of said optical substrate, said optical substrate and said substance thereon collectively defining a multi-section substrate in which said optical substrate and said optical layer serve as respective sections.

2. A method according to claim 1, including after said depositing, selectively removing material from said multi-section substrate to impart a selected shape thereto.

3. A method according to claim 2,
wherein after said removing said multi-section substrate has a surface portion on an exterior thereof; and
including after said removing, depositing an optical coating on said surface portion of said modified substrate.

4. A method according to claim 1, including selecting said substance so that a hardness thereof is approximately equal to a hardness of said optical substrate.

5. A method according to claim 1, including selecting said substance so that a coefficient of thermal expansion thereof is approximately equal to a coefficient of thermal expansion of said optical substrate.

6. A method according to claim 1, including selecting as said substance a material from which said optical substrate is made.

7. A method according to claim 1, wherein said depositing is carried out in a manner that includes:
supporting said optical substrate within an evaporation chamber; and
evaporating said substance in an evaporation source disposed within said chamber.

8. A method according to claim 1, wherein said depositing is carried out in a manner that includes:
supporting said optical substrate within an evaporation chamber; and
evaporating in an evaporation source disposed within said chamber a plurality of materials that are each a respective component of said substance.

9. A method according to claim 1, wherein said depositing is carried out in a manner that includes:
supporting said optical substrate within a sputtering chamber; and
carrying out sputtering using a sputter target that emits said substance during sputtering.

10. A method according to claim 1, wherein said multi-section substrate is one of an optical lens and an optical window.

11. An apparatus comprising a multi-section substrate having a first section that is an optical substrate with a surface, and having a second section that is an optical layer provided on said surface and made of a substance having an index of refraction approximately equal to an index of refraction of said optical substrate.

12. An apparatus according to claim 11,
wherein said multi-section substrate has a surface portion on an exterior thereof; and
including an optical coating on said surface portion of said multi-section substrate.

13. An apparatus according to claim 11, wherein said substance has a hardness that is approximately equal to a hardness of said optical substrate.

14. An apparatus according to claim 11, wherein said substance has a coefficient of thermal expansion similar to a coefficient of thermal expansion of said optical substrate.

15. An apparatus according to claim 11, wherein said optical substrate is made of said substance.

16. An apparatus according to claim 11, wherein said multi-section substrate is one of an optical lens and an optical window.
